(19) United States
(12) Patent Application Publication
(10) Pub. No.: US 2026/0026345 A1
(43) Pub. Date: Jan. 22, 2026

(54) SEMICONDUCTOR PACKAGE

(71) Applicant: Samsung Electronics Co., Ltd., Suwon-si (KR)

(72) Inventors: Kyomuk LIM, Suwon-si (KR); Myeongho HONG, Suwon-si (KR); Jangbae SON, Suwon-si (KR); Hyunseok CHOI, Suwon-si (KR)

(73) Assignee: Samsung Electronics Co., Ltd., Suwon-si (KR)

(21) Appl. No.: 19/073,667

(22) Filed: Mar. 7, 2025

(30) Foreign Application Priority Data
Jul. 16, 2024 (KR) 10-2024-0093647

(51) Int. Cl. H01L 23/373; H01L 23/00; H01L 23/31; H01L 23/498

(52) U.S. Cl. CPC H01L 23/3732; H01L 23/49827; H01L 24/24; H01L 24/25; H01L 23/3185; H01L 2224/2405; H01L 2224/244; H01L 2224/2518

(57) ABSTRACT

According to some example embodiments, a semiconductor package includes a first redistribution layer (RDL) including a first redistribution wiring structure, a substrate on the first RDL and including a wiring structure and having a rectangular ring shape, a semiconductor chip on the first RDL and in a space defined by the substrate, a heat dissipation block between the semiconductor chip and the substrate on the first RDL, a molding member on the first RDL and covering sidewalls of the semiconductor chip and the heat dissipation block and an inner sidewall of the substrate, and a second RDL on the semiconductor chip, the heat dissipation block, the substrate and the molding member and including a second redistribution wiring structure. A planar area of the heat dissipation block is greater than a planar of the semiconductor chip.

### CROSS-REFERENCE TO RELATED APPLICATION

This U.S. non-provisional application claims priority under 35 U.S.C. § 119 to Korean Patent Application No. 10-2024-0093647 filed on Jul. 16, 2024, in the Korean Intellectual Property Office (KIPO), the contents of which are herein incorporated by reference in their entirety.

### BACKGROUND

Some example embodiments relate to a semiconductor package.

A die included in a fan out wafer level package (FOWLP) generates a relatively large amount of heat, and it is advantageous to dissipate the generated heat.

### SUMMARY

Some example embodiments provide a semiconductor package having improved electrical characteristics.

According to some example embodiments, a semiconductor package may include a first redistribution layer (RDL) including a first redistribution wiring structure, a substrate on the first RDL and including a wiring structure and having a rectangular ring shape, a semiconductor chip on the first RDL and in a space defined by the substrate, a heat dissipation block between the semiconductor chip and the substrate on the first RDL, a molding member on the first RDL and covering sidewalls of the semiconductor chip and the heat dissipation block and an inner sidewall of the substrate, and a second RDL on the semiconductor chip, the heat dissipation block, the substrate and the molding member and the second RDL including a second redistribution wiring structure. A planar area of the heat dissipation block may be greater than a planar of the semiconductor chip.

According to some example embodiments, a semiconductor package may include a first redistribution layer (RDL) including a first redistribution wiring structure, a substrate on the first RDL and including a wiring structure and having a rectangular ring shape, a semiconductor chip on the first RDL and in a space defined by the substrate, heat dissipation blocks between the semiconductor chip and the substrate on the first RDL, a molding member on the first RDL and covering sidewalls of the semiconductor chip and the heat dissipation blocks and an inner sidewall of the substrate, and a second RDL on the semiconductor chip, the heat dissipation blocks, the substrate and the molding member and the second RDL including a second redistribution wiring structure. At least a portion of the heat dissipation blocks may be interposed between the semiconductor chip and the substrate in a horizontal direction.

According to some example embodiments, a semiconductor package may include a first redistribution layer (RDL) including first to fourth redistribution wiring structures, conductive connection members below and electrically connected to the first to fourth redistribution wiring structures, respectively, a substrate on the first RDL, including a wiring structure and having a rectangular ring shape, a semiconductor chip on the first RDL and in a space defined by the substrate, a heat dissipation block between the semiconductor chip and the substrate on the first RDL, a molding member on the first RDL and covering sidewalls of the semiconductor chip and the heat dissipation block and an inner sidewall of the substrate, and a second RDL on the semiconductor chip, the heat dissipation block, the substrate and the molding member and the second RDL including fifth to seventh redistribution wiring structures. A planar area of the heat dissipation block may be greater than a planar of the semiconductor chip. The first redistribution wiring structure may be disposed on and contact a lower surface of the semiconductor chip, the second redistribution wiring structure may be disposed on and contact a lower surface of the heat dissipation block, the third redistribution wiring structure may be disposed on and contact lower surfaces of the semiconductor chip and the heat dissipation block, and the fourth redistribution wiring structure may be disposed on and contact a lower surface of the wiring structure. The fifth redistribution wiring structure may be disposed on and contact an upper surface of the semiconductor chip, the sixth redistribution wiring structure may be disposed on and contact an upper surface of the heat dissipation block, and the seventh redistribution wiring structure may be disposed on and contact an upper surface of the wiring structure.

According to some example embodiments, the semiconductor package may include a heat dissipation block having a relatively larger planar area, and may have improved heat dissipation characteristics.

### BRIEF DESCRIPTION OF THE DRAWINGS

FIG. 1 is a cross-sectional view illustrating a semiconductor package, according to some example embodiments.

FIG. 2 is a plan view illustrating a layout of a first semiconductor chip, a first heat dissipation block and a first molding member included in the semiconductor package of FIG. 1, according to some example embodiments.

FIGS. 3, 4, 5, 6, 7, 8, 9, 10, 11, and 12 are plan views and cross-sectional views illustrating operations in a method of manufacturing a semiconductor package, according to some example embodiments.

FIGS. 13, 14, 15, and 16 are plan views illustrating layouts of the first semiconductor chip, the first heat dissipation block and the first molding member included in the semiconductor package, according to some example embodiments.

FIGS. 17 and 18 are cross-sectional views illustrating a package on package (POP), according to some example embodiments.

FIG. 19 is a cross-sectional view illustrating an electronic device, according to some example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

For the purposes of discussion herein, two crossing (or transverse) directions among horizontal directions that are substantially parallel to an upper surface of a panel or a substrate may be referred to as first and second directions D1 and D2, respectively, and a vertical direction that is substantially perpendicular to the upper surface of the panel or the substrate may be referred to a third direction D3. In some example embodiments, the first and second directions D1 and D2 may be substantially perpendicular to each other.

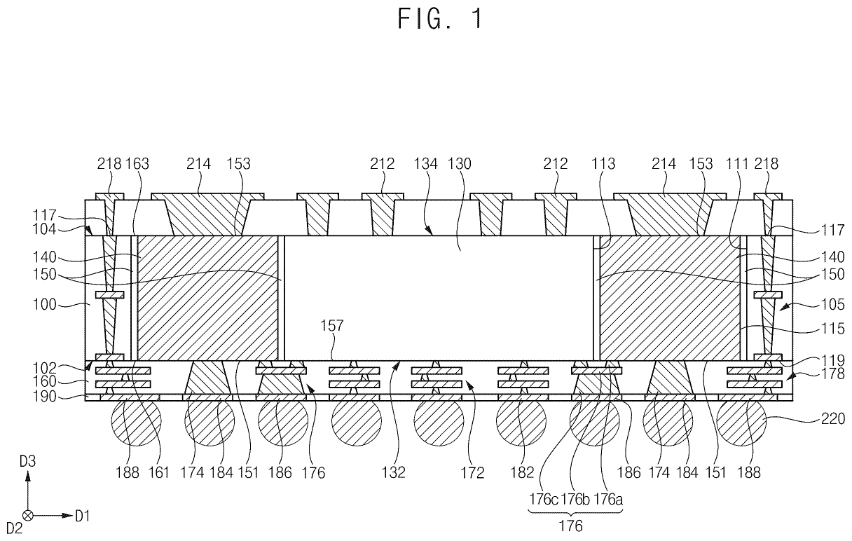

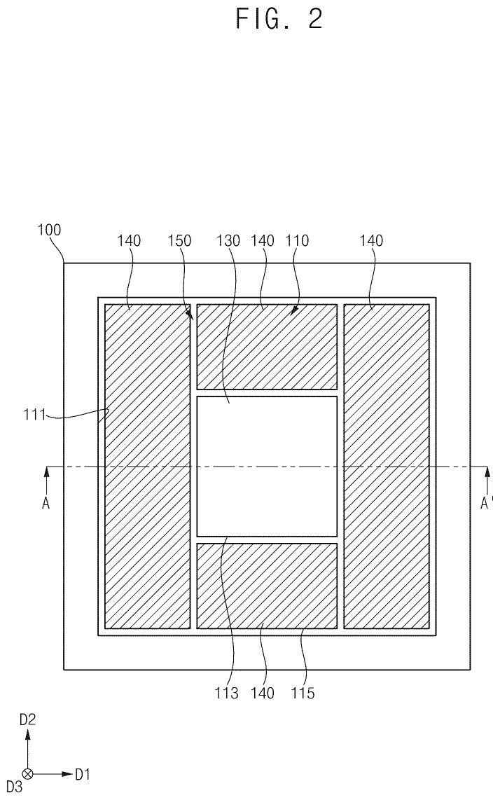

FIG. 1 is a cross-sectional view illustrating a semiconductor package, according to some example embodiments. FIG. 2 is a plan view illustrating a layout of a first semiconductor chip 130, a first heat dissipation block 140 and a first molding member 150 included in the semiconductor package of FIG. 1. FIG. 1 corresponds to a cross-sectional view taken along line A-A′ of FIG. 2.

Referring to FIGS. 1 and 2, the semiconductor package may include a first redistribution layer (RDL) 160 including first to fourth redistribution wiring structures 172, 174, 176 and 178, a first substrate 100 on the first RDL 160, and the first semiconductor chip 130 and the first heat dissipation block 140 arranged spaced apart from each other in the horizontal direction in a space or region defined by the first substrate 100 on the first RDL 160. The semiconductor package may further include the first molding member 150 in spaces between the first substrate 100, the first semiconductor chip 130 and the first heat dissipation block 140 on the first RDL 160, and a second RDL 200 including fifth to seventh redistribution wiring structures on the first substrate 100, the first semiconductor chip 130, the first heat dissipation block 140 and the first molding member 150.

The semiconductor package may further include first to fourth conductive pads 182, 184, 186 and 188 below the first RDL 160, a first protective layer 190 below the first RDL 160 and covering sidewalls of the first to fourth conductive pads 182, 184, 186 and 188, and a plurality of first conductive connection members 220, each contacting lower surfaces of the corresponding first to fourth conductive pads 182, 184, 186 and 188.

In some example embodiments, the semiconductor package may further include a second protective layer on the second RDL 200 and covering sidewalls of the fifth to seventh redistribution wiring structures.

The first substrate 100 may include first and second surfaces 102 and 104 opposite to each other in the third direction D3, and the first surface 102 of the first substrate 100 may contact an upper surface of the first RDL 160. The first substrate 100 may be or include a resin, e.g., polypropylene glycol (PPG).

In some example embodiments, the first substrate 100 may have a rectangular ring shape or a frame shape, as illustrated in FIG. 2.

A wiring structure 105 may be disposed in the first substrate 100. The wiring structure 105 may include, e.g., pads, contact plugs, vias, wirings, and the like, some of which are shown in FIG. 1. Each of the pads, the contact plugs, the vias, the wirings, and the like may be or include a conductive material, e.g., a metal, a metal nitride, a metal silicide, a combination thereof, and the like.

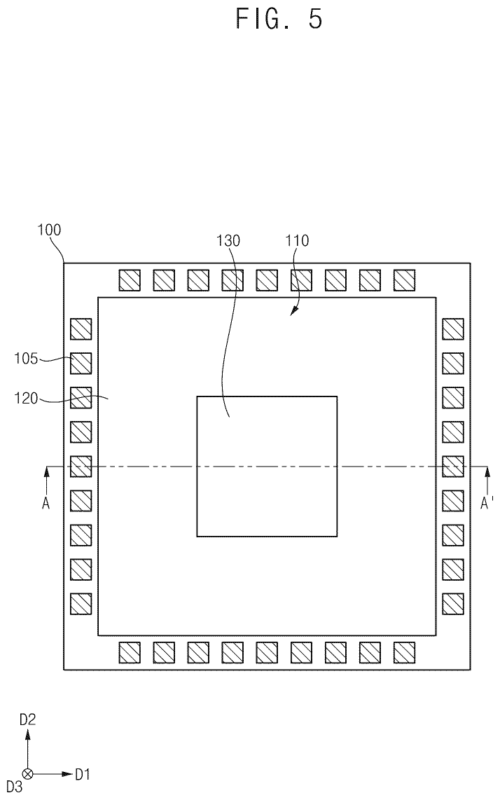

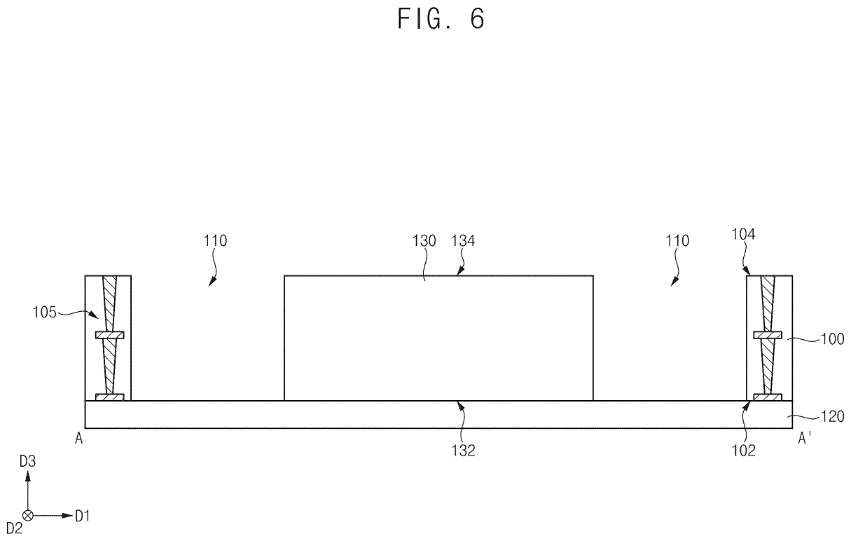

Referring to FIGS. 1 and 2, with brief reference to FIGS. 5 and 6, the first semiconductor chip 130 may be disposed in an opening 110 defined in the first substrate 100. The first semiconductor chip 130 may include first (or lower) and second (or upper) surfaces 132 and 134 opposite to each other in the third direction D3, and the first surface 132 may be referred to as an active surface. The first surface 132 of the first semiconductor chip 130 may contact an upper surface of the first RDL 160 exposed by the opening 110. In some example embodiments, the first surface 132 of the first semiconductor chip 130 may contact an upper surface of a portion of the first RDL 160 exposed in a central portion of the opening 110, and chip pads may be disposed in portions of the first semiconductor chip 130 adjacent to the first surface 132.

The first semiconductor chip 130 may include, e.g., logic devices, memory devices, and the like, and thus may also be referred to as a logic chip, a memory chip, and the like, or a logic die, a memory die, etc.

In some example embodiments, the first semiconductor chip 130 may be rectangular or square shaped having opposite sides that may extend in the first and second directions D1 and D2, respectively, in a plan view.

The first heat dissipation block 140 may be disposed between the first substrate 100 and the first semiconductor chip 130. The first heat dissipation block 140 may have first (or lower) and second (or upper) surfaces 151 and 153 opposite to each other in the third direction D3, and the first surface 151 of the first heat dissipation block 140 may contact the upper surface 157 of the first RDL 160. In some example embodiments, first and second surfaces 151 and 153 of the heat dissipation block 140 are coplanar with first and second surfaces 132 and 134, respectively, of the semiconductor chip 130.

In some example embodiments, and as illustrated, a plurality of first heat dissipation blocks 140 may be arranged spaced apart from each other in each of the first and second directions D1 and D2, and each of the plurality of first heat dissipation blocks 140 may be arranged spaced apart from the first semiconductor chip 130. In some example embodiments, each of the first heat dissipation blocks 140 may be rectangular or square shaped having opposite sides that may extend in the first and second directions D1 and D2, respectively, in a plan view, and may be disposed on each of opposite sides in the first direction D1 and on each of opposite sides in the second direction D2 of the first semiconductor chip 130.

In some example embodiments, a length in the second direction D2 of the first heat dissipation blocks 140 arranged on opposite sides of the first semiconductor chip 130 in the first direction D1 may be greater than a length in the second direction D2 of the first semiconductor chip 130. In some example embodiments, a length in the first direction D1 of the first heat dissipation blocks 140 arranged on opposite sides of the first semiconductor chip 130 in the second direction D2 may be equal (or substantially equal) to a length in the first direction D1 of the first semiconductor chip 130.

In some example embodiments, the first heat dissipation block 140 may be or include a material having a relatively higher heat conductivity. In some example embodiments, the first heat dissipation block 140 may be or include a metal such as copper, gold, aluminum, or the like, or may be or include diamond or graphene.

The first molding member 150 may be disposed or arranged on the first RDL 160, and may cover sidewalls 113 of the first semiconductor chip 130, the sidewalls 115 of the first heat dissipation block 140, and an inner sidewall 111 of the first substrate 100. The first molding member 150 may include first and second surfaces 161 and 163 opposite to each other in the third direction D3, and the first surface 161 of the first molding member 150 may contact the upper surface 157 of the first RDL 160.

In some example embodiments, the first molding member 150 may include an organic material, for instance, epoxy, polymer, and the like. In some example embodiments, the first molding member 150 may include Ajinomoto build-up film (ABF) having a stacked structure including a polybutylene terephthalate (PET) film, a thermosetting resin and a protective film. Alternatively or additionally, the first molding member 150 may include epoxy molding compound (EMC).

The first RDL 160 may include first insulating interlayers stacked in the third direction D3 and first to fourth redistribution wiring structures 172, 174, 176 and 178 in the first insulating interlayers. However, the redistribution wiring structures are not limited to four, and, in some example embodiments, the first RDL 160 may include three or less redistribution wiring structures, or may include five or more redistribution wiring structures.

In some example embodiments, each of the first to fourth redistribution wiring structures 172, 174, 176 and 178 may include, pads, contact plugs, vias, wirings, and the like, as illustrated in FIG. 1.

The first redistribution wiring structure 172 may be disposed below the first surface 132 of the first semiconductor chip 130, and may, for example, contact, the chip pads of the first semiconductor chip 130 and may be electrically connected thereto. The second redistribution wiring structure 174 may be disposed below the first heat dissipation block 140 and contact the first surface of the first heat dissipation block 140 and may be electrically connected thereto. The third redistribution wiring structure 176 may be disposed below the first semiconductor chip 130 and the first heat dissipation block 140, and contact the first surface 132 of the first semiconductor chip 130 and the first surface of the first heat dissipation block 140 and may be electrically electronically connected to the first semiconductor chip 130 and the first heat dissipation block 140. The fourth redistribution wiring structure 178 may be disposed below the first surface 102 of the first substrate 100 and may contact a lower surface 119 of the wiring structure 105 and may be electrically connected thereto.

Some of the first to fourth redistribution wiring structures 172, 174, 176 and 178 may be connected to each other. For example, in some example embodiments, the first and fourth redistribution wiring structures 172 and 178 may be electrically connected to each other, and thus electrical signals generated from the first semiconductor chip 130 may be transferred to the fourth redistribution wiring structure 178 through the first redistribution wiring structure 172.

In some example embodiments, the second redistribution wiring structure 174 may be or include a first via 174 extending through the first RDL 160. The third redistribution wiring structure 176 may include two (or more) second vias 176a (two shown). One of the second vias 176a may contact the first surface 132 of the first semiconductor chip 130 and the other of the second vias 176a may contact the first surface of the first heat dissipation block 140. The third redistribution wiring structure 176 may further include a first wiring 176b that may contact lower surfaces of both the two second vias 176a, and a third via 176c that may contact a lower surface of the first wiring 176b.

In some example embodiments, each of the first to third vias 174, 176a and 176c may be a generally conical structure having a width in the horizontal direction gradually decreasing from a bottom toward a top thereof. In some example embodiments, the horizontal width of the first via 174 may be greater than the horizontal widths of the second and third vias 176a and 176c. Additionally or alternatively, the horizontal width of each of the second and third vias 176a and 176c may be greater than that of each of the vias included in the first and fourth redistribution wiring structures 172 and 178.

In some example embodiments, the first insulating interlayer of the first RDL 160 may include an organic material, for instance, photo imageable dielectric (PID), and each of the pads, the contact plugs, the vias and the wirings may include a conductive material, for instance, a metal, a metal nitride, a metal silicide, and the like.

The first to fourth conductive pads 182, 184, 186 and 188 may contact the first to fourth redistribution wiring structures 172, 174, 176 and 178, respectively. Each of the first to fourth conductive pads 182, 184, 186 and 188 may be or include a conductive material, including, for example, a metal, a metal nitride, a metal silicide, and the like. The first protective layer 190 covering the sidewalls of the first to fourth conductive pads 182, 184, 186 and 188 may include an organic insulating material including, for example, solder resist (SR), or an inorganic insulating material including, for example, silicon oxide, silicon nitride, and the like.

In some example embodiments, a plurality of first conductive connection members 220 may be spaced apart from each other in the horizontal direction and may contact lower surfaces of the first to fourth conductive pads 182, 184, 186 and 188, respectively. The first conductive connection members 220 may be or include a conductive bump or a conductive ball including, for example, solder.

The fifth to seventh redistribution wiring structures included in the second RDL 200 may contact the second surface 134 of the first semiconductor chip 130, the second surface 153 of the first heat dissipation block 140, and upper surfaces 117 of portions of the wiring structure 105 disposed on the second surface 104 of the first substrate 100, respectively, and may be electrically connected thereto. In some example embodiments, the fifth to seventh redistribution wiring structures may be or include fourth to sixth vias 212, 214 and 218, respectively, however, example embodiments are not limited thereto.

In some example embodiments, each of the fourth to sixth vias 212, 214 and 218 may include a lower portion extending through the second RDL 200, and an upper portion that may be disposed on the lower portion and protrude over an upper surface of the second RDL 200 and have a planar area greater than that of the lower portion. In some example embodiments, a planar area of the fifth via 214 may be greater than a planar area of the fourth via 212, and the planar area of the fourth via 212 may be greater than a planar area of the sixth via 218.

In some example embodiments, pads, contact plugs, vias, wirings, and the like, may be further disposed in the second RDL 200 in addition to the fifth to seventh redistribution wiring structures.

In the semiconductor package, the first heat dissipation blocks 140 may surround the first semiconductor chip 130, and a sum of planar areas (or cross-sectional areas) of the first heat dissipation blocks 140 may be greater than a planar area of the first semiconductor chip 130. Thus, heat generated from the first semiconductor chip 130 may be efficiently dissipated away and out of the semiconductor package.

Heat generated from the first semiconductor chip 130 may be transferred (or dissipated) away from the first semiconductor chip 130 through the third redistribution wiring structure 176, the first heat dissipation block 140, and the sixth redistribution wiring structure including the fifth via 214, or through the third redistribution wiring structure 176, the third conductive pad 186 and the first conductive connection member 220, or through the fifth redistribution wiring structure including the fourth via 212. As such, the heat generated may be dissipated away from the first semiconductor package using multiple paths.

A plurality of first heat dissipation blocks 140 may be arranged to surround the first semiconductor chip 130 in the plan view (FIG. 2) and the plurality of first heat dissipation blocks 140 may be spaced apart from each other. A sum of planar areas (or cross-sectional areas) of the first heat dissipation blocks 140 may be greater than that of the first semiconductor chip 130. The fifth via 214 included in the sixth redistribution wiring structure 214 may also have a relatively larger planar area (for instance, compared to the fourth and sixth vias 212 and 218). Thus, the heat dissipation through the first heat dissipation blocks 140 and the fifth via 214 may be improved or maximized.

Additionally, the second and third vias 176a and 176c included in the third redistribution wiring structure 176 may also have a relatively larger planar area, and heat may be transferred (or dissipated) therethrough with improved efficiency. Furthermore, the fourth vias 212 included in the fifth redistribution wiring structure may also have a relatively larger planar area and heat may be transferred (or dissipated) therethrough with improved efficiency.

Accordingly, the semiconductor package including the first heat dissipation block 140, the second and third redistribution wiring structures 174 and 176, and the fifth and sixth redistribution wiring structures may have improved heat dissipation characteristics.

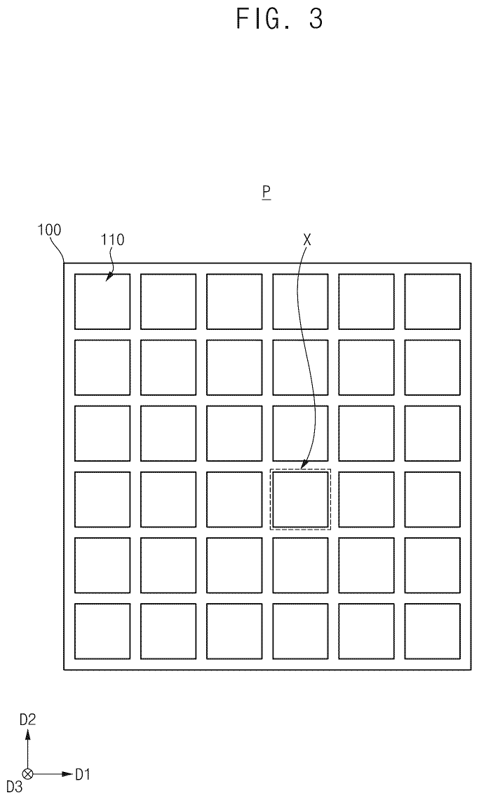

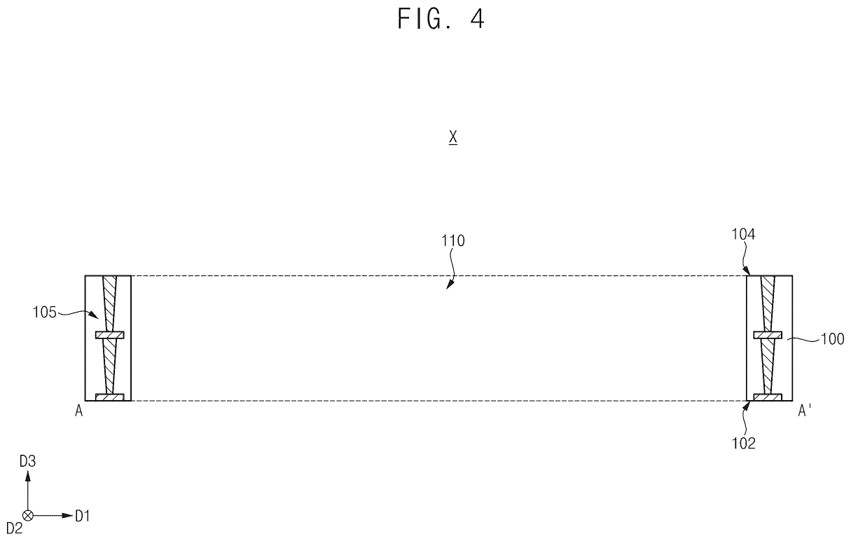

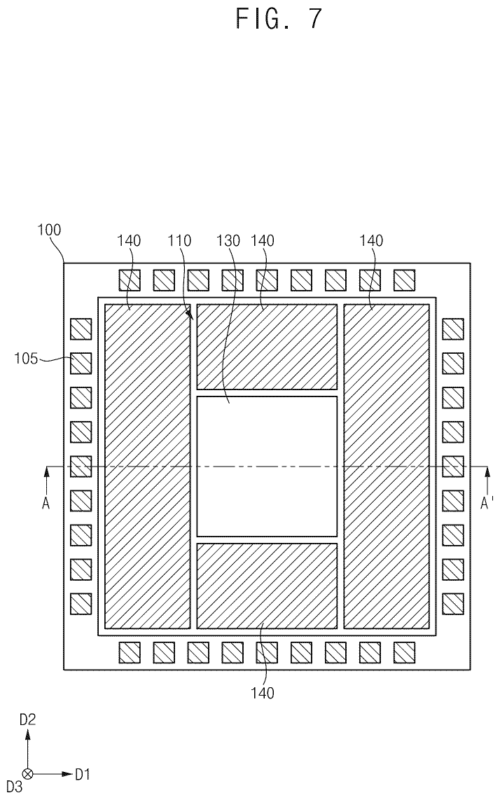

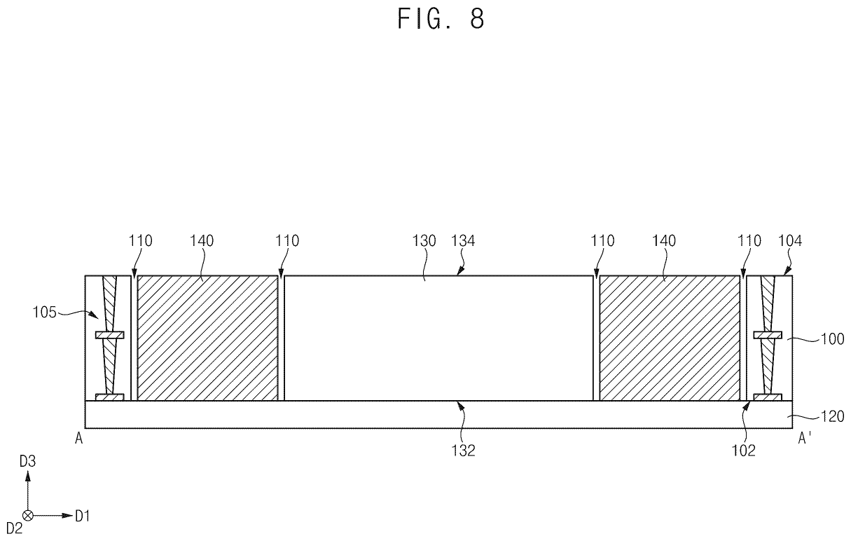

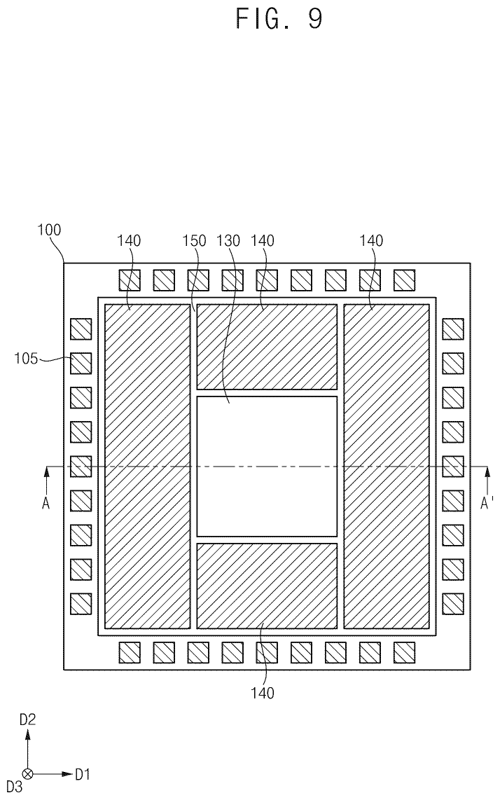

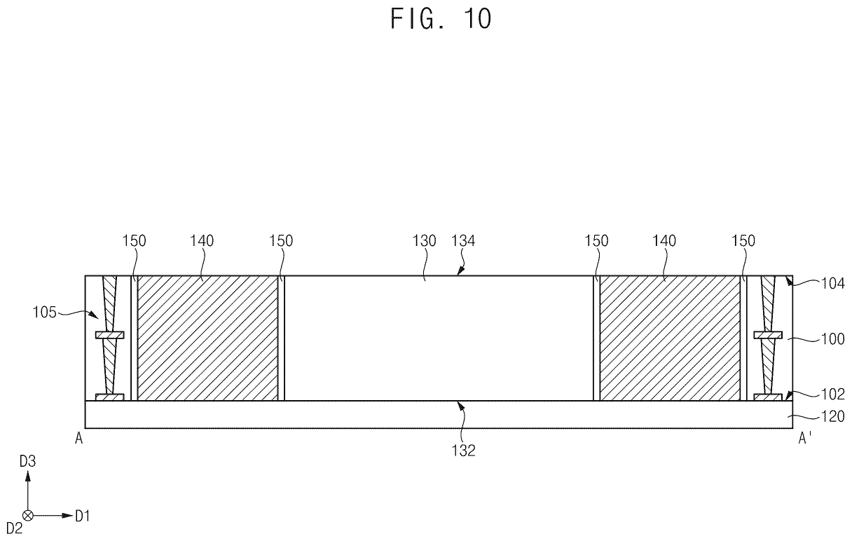

FIGS. 3 to 12 are plan views and cross-sectional views illustrating a method of manufacturing a semiconductor package, according to some example embodiments. FIGS. 3, 5, 7 and 9 are the plan views, and FIGS. 4, 6, 8 and 10-12 are cross-sectional views. FIG. 6 is a cross-sectional view taken along line A-A′ in the plan view of FIG. 5. FIG. 8 is a cross-sectional view taken along line A-A′ in the plan view of FIG. 7. FIG. 10 is a cross-sectional view taken along line A-A′ in the plan view of FIG. 9. FIGS. 4 to 12 are drawings of a region X of FIG. 3.

Referring to FIGS. 3 and 4, in some example embodiments, a laser process may be performed on a panel P including a first substrate 100 to form an opening 110 through the first substrate 100.

The first substrate 100 may include first and second surfaces 102 and 104 opposite to each other in the third direction D3.

The panel P may include a plurality of die regions and a scribe lane region surrounding each of the die regions, and the panel P may be cut along the scribe lane region by a sawing process to obtain individual die regions.

In each of the die regions of the panel P, a wiring structure 105 extending through the first substrate 100 may be formed. In some example embodiments, the wiring structure 105 may include pads, contact plugs, vias, wirings, and the like, some of which are shown in FIG. 4.

In some example embodiments, the opening 110 may be formed in a central portion of each of the die regions of the panel P, and thus a plurality of openings 110 may be formed spaced apart from each other in each of the first and second directions D1 and D2.

Referring to FIGS. 5 and 6, the panel P may be mounted on a first adhesion layer 120 using a stage or support for securing the panel P.

When the panel P is mounted on the stage, the first surface 102 of the first substrate 100 may contact an upper surface of the first adhesion layer 120, and thus an upper surface of a portion of the first adhesion layer 120 may be exposed by the opening 110.

The first adhesion layer 120 may include a material that may lose adhesive property by irradiating light or heating. In some example embodiments, the first adhesion layer 210 may include a release tape.

A first semiconductor chip 130 may be mounted on the upper surface of the first adhesion layer 120 exposed by the opening 110. In some example embodiments, the first semiconductor chip 130 may be mounted on an upper surface of a portion of the first adhesion layer 120 exposed by a central portion of the opening 110.

The first semiconductor chip 130 may include first and second surfaces 132 and 134 opposite to each other in the third direction D3, and the first surface 132 of the first semiconductor chip 130 may contact the upper surface of the portion of the first adhesion layer 120 exposed by the opening 110. In some example embodiments, chip pads in the first semiconductor chip 130 may contact the upper surface of the first adhesion layer 120.

Referring to FIGS. 7 and 8, a first heat dissipation block 140 may be mounted on the upper surface of the first adhesion layer 120 exposed by the opening 110. In some example embodiments, the first heat dissipation block 140 may be mounted on portions of the upper surface of the first adhesion layer 120 in the opening 110 that remains exposed after mounting the first semiconductor chip 130.

The first heat dissipation block 140 may include first and second surfaces opposite to each other in the third direction D3, and the first surface of the first heat dissipation block 140 may contact the upper surface of the first adhesion layer 120.

The first heat dissipation block 140 may be spaced apart from the first semiconductor chip 130 and the first substrate 100 in the horizontal direction. In some example embodiments, a plurality of first heat dissipation blocks 140 may arranged surrounding (or about) the first semiconductor chip 130 and spaced apart from each other in the horizontal direction. The plurality of first heat dissipation blocks 140 may be disposed on opposite sides of the first semiconductor chip 130 in the first direction D1 and opposite sides of the first semiconductor chip 130 in the second direction D2.

Referring to FIGS. 9 and 10, a first molding layer may be formed on the first adhesion layer 120, the first semiconductor chip 130 and the first heat dissipation block 140 to fill the opening 110. In some example embodiments, a griding process may be performed to remove upper portions of the first molding layer.

The grinding process may expose the second surface 134 of the first semiconductor chip 130 and the second surface of the first heat dissipation block 140, and a first molding member 150 may be formed in the opening 110. The first molding member 150 may include first and second surfaces opposite to each other in the third direction D3, and the first surface of the first molding member 150 may contact the upper surface of the first adhesion layer 120.

After the grinding process, a cleansing process may be further performed to remove any remaining first molding layer on the second surface 134 of the first semiconductor chip 130 and the second surface of the first heat dissipation block 140, and the first adhesion layer 120 may be removed from the first substrate 100, the first semiconductor chip 130, the first heat dissipation block 140 and the first molding member 150.

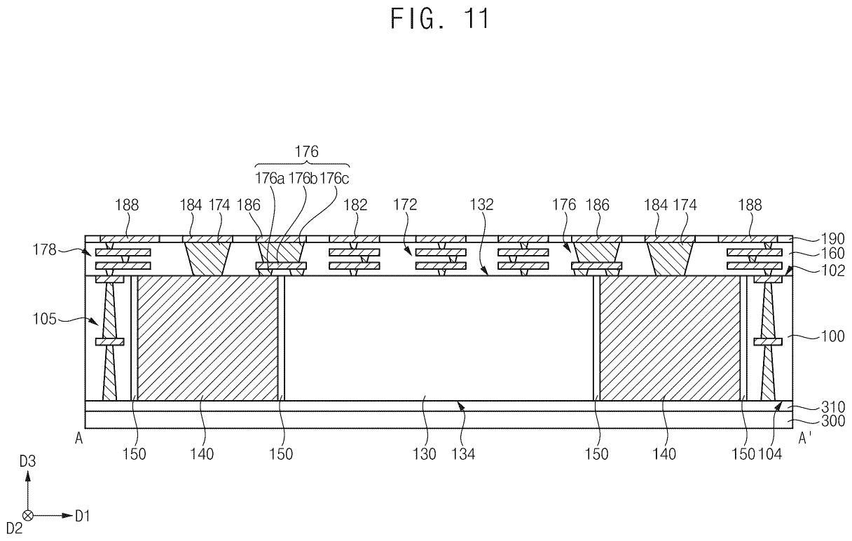

Referring to FIG. 11, a first carrier substrate 300 may be bonded to the second surface 104 of the first substrate 100, the second surface 134 of the first semiconductor chip 130, the second surface of the first heat dissipation block 140 and the second surface of the first molding member 150, using a second adhesion layer 310.

In some example embodiments, the first carrier substrate 300 may include a semiconductor material, an organic material, glass, and the like, and the second adhesion layer 310 may include a release tape or an epoxy such as ABF.

A first RDL 160 may be formed on the first surface 102 of the first substrate 100, the first surface 132 of the first semiconductor chip 130, the first surface of the first heat dissipation block 140 and the first surface of the first molding member 150. The first RDL 160 may include first insulating interlayers stacked in the third direction D3, and first to fourth redistribution wiring structures 172, 174, 176 and 178 in the first insulating interlayers. In some example embodiments, each of the first to fourth redistribution wiring structures 172, 174, 176 and 178 may include pads, contact plugs, vias, wirings, and the like.

In some example embodiments, the first redistribution wiring structure 172 may be disposed on the first semiconductor chip 130, the second redistribution wiring structure 174 may be disposed on the first heat dissipation block 140, the third redistribution wiring structure 176 may be disposed on the first semiconductor chip 130 and the first heat dissipation block 140 adjacent each other, and the fourth redistribution wiring structure 178 may be disposed on the first substrate 100.

A first to fourth conductive pads 182, 184, 186 and 188 may be formed on the first RDL 160, and a first protective layer 190 may be formed to cover sidewalls of the first to fourth conductive pads 182, 184, 186 and 188. The first to fourth conductive pads 182, 184, 186 and 188 may be formed on and contact the first to fourth redistribution wiring structures 172, 174, 176 and 178, respectively. The assembly above including the panel P may be flipped.

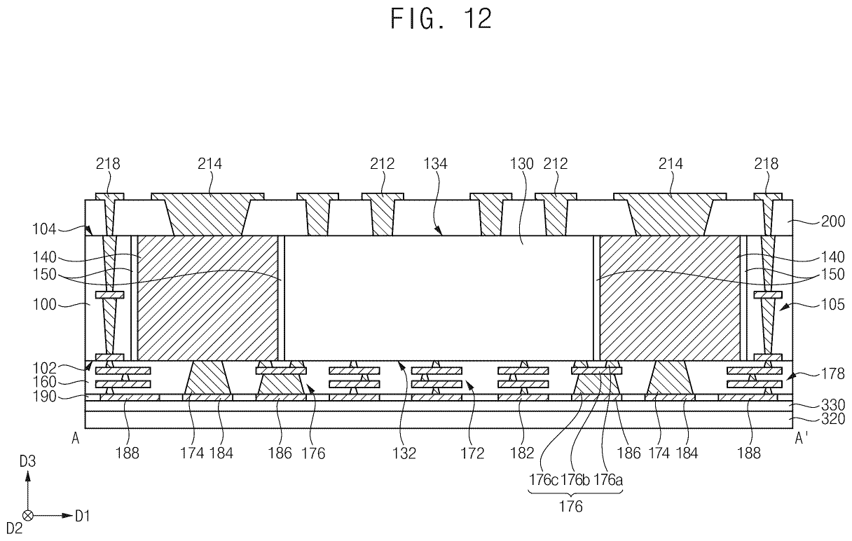

Referring to FIG. 12, a second carrier substrate 320 may be bonded to surfaces of the first to fourth conductive pads 182, 184, 186 and 188 and the protective layer 190, using a third adhesion layer 330.

In some example embodiments, the second carrier substrate 320 may include a semiconductor material, an organic material, glass, and the like, and the third adhesion layer 330 may include a release tape or an epoxy such as ABF.

After removing the second adhesion layer 310 and the first carrier substrate 300, a second RDL 200 may be formed on the second surface 104 of the first substrate 100, the second surface 134 of the first semiconductor chip 130, the second surface of the first heat dissipation block 140 and the second surface of the first molding member 150. The second RDL 200 may include second insulating interlayers stacked in the third direction D3, and fifth to seventh redistribution wiring structures 212, 214 and 218 in the second insulating interlayers. In some example embodiments, each of the fifth to seventh redistribution wiring structures 212, 214 and 218 may include pads, contact plugs, vias, wirings, and the like.

In some example embodiments, the fifth redistribution wiring structure 212 may be disposed on the first semiconductor chip 130, the sixth redistribution wiring structure 214 may be disposed on the first heat dissipation block 140, and the seventh redistribution wiring structure 218 may be disposed on the first substrate 100.

A second protective layer may be further formed on the second RDL 200 to cover the fifth to seventh redistribution wiring structures 212, 214 and 218.

Referring to FIGS. 1 and 2 again, first conductive connection members 220 may be formed on surfaces of the first to fourth conductive pads 182, 184, 186 and 188, and the panel P may be cut along the scribe lane region, for example using a sawing process, to obtain a plurality of first substrates 100.

During the sawing process, structures on and beneath the panel P may also be cut, which may form a unit semiconductor package together with the panel P.

By the above processes, the semiconductor package may be manufactured.

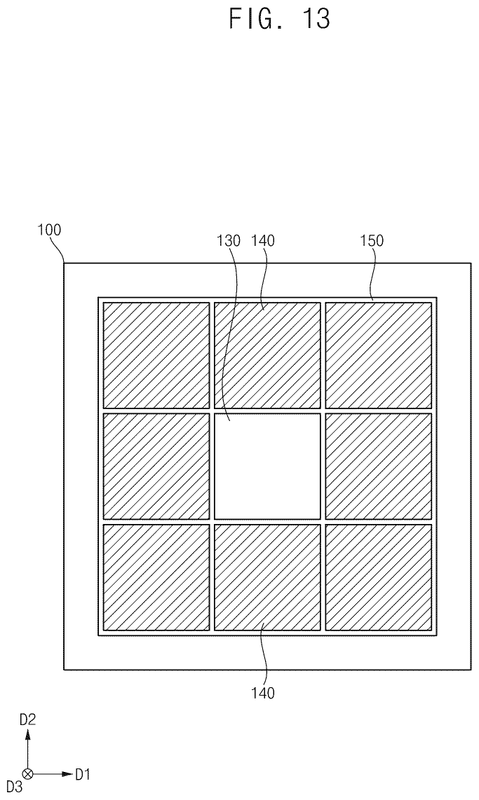

FIGS. 13 to 16 are plan views illustrating layouts of the first semiconductor chip 130, the first heat dissipation block 140 and the first molding member 150 included in the semiconductor package, which may correspond to FIG. 2.

Referring to FIG. 13, a plurality of first heat dissipation blocks 140 may be spaced apart from each other in each of the first and second directions D1 and D2, and each of the plurality of first heat dissipation blocks 140 may be square shaped in a plan view.

A planar area (or cross-sectional area) of each of the plurality of first heat dissipation blocks 140 may be equal (or substantially equal) to a planar area (or cross-sectional area) of the first semiconductor chip 130, and the first heat dissipation blocks 140 and the first semiconductor chip 130 may be arranged in a lattice pattern in a plan view.

In some example embodiments, the first heat dissipation blocks 140 may have the same shape, and thus cost and time for manufacturing the first heat dissipation blocks 140 may decrease or minimized.

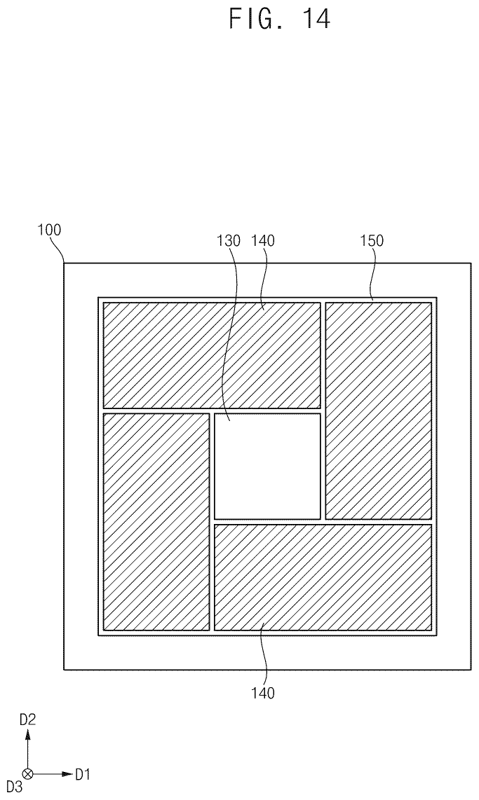

Referring to FIG. 14, each of the plurality of first heat dissipation blocks 140 may have a rectangular shape in a plan view, and the first heat dissipation blocks 140 may be arranged in a clockwise direction or a counter-clockwise direction around the first semiconductor chip 130.

In some example embodiments, a length of a long side of each of the first heat dissipation blocks 140 may be greater than a length in each of the first and second directions D1 and D2 of the first semiconductor chip 130, and a length of a short side of each of the first heat dissipation blocks 140 may be smaller than or equal (or substantially equal) to the length in each of the first and second directions D1 and D2 of the first semiconductor chip 130.

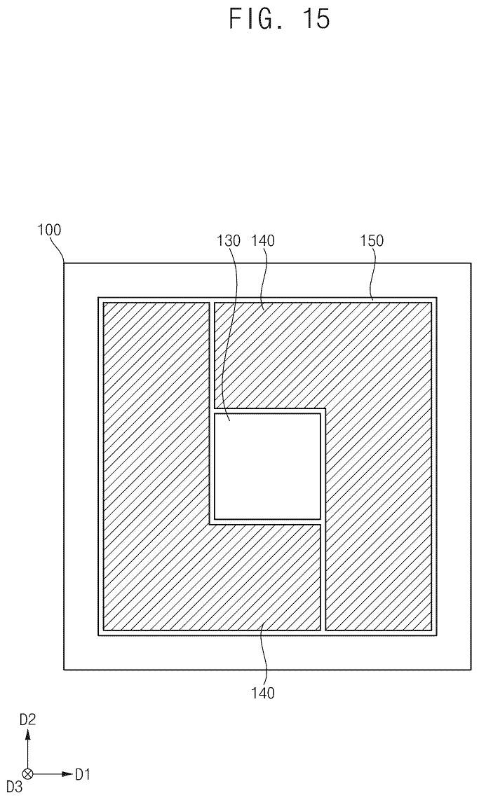

Referring to FIG. 15, each of the first heat dissipation blocks 140 may have an “L” shape in a plan view and may be arranged in point symmetry around the first semiconductor chip 130.

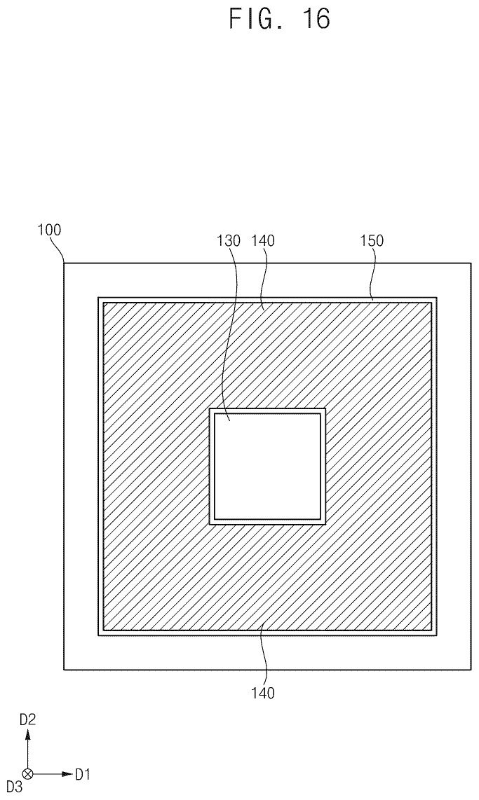

Referring to FIG. 16, the first heat dissipation block 140 may have a rectangular ring shape (or a frame shape) and may surround the first semiconductor chip 130 in a plan view.

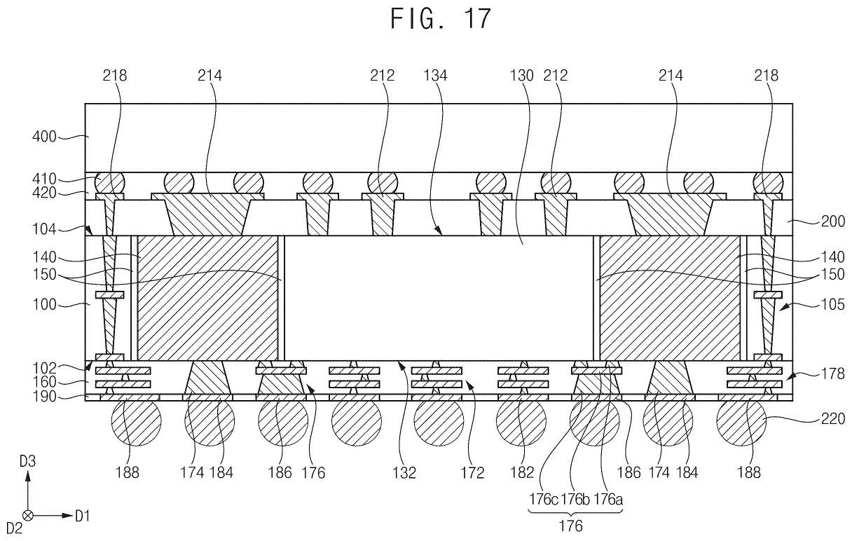

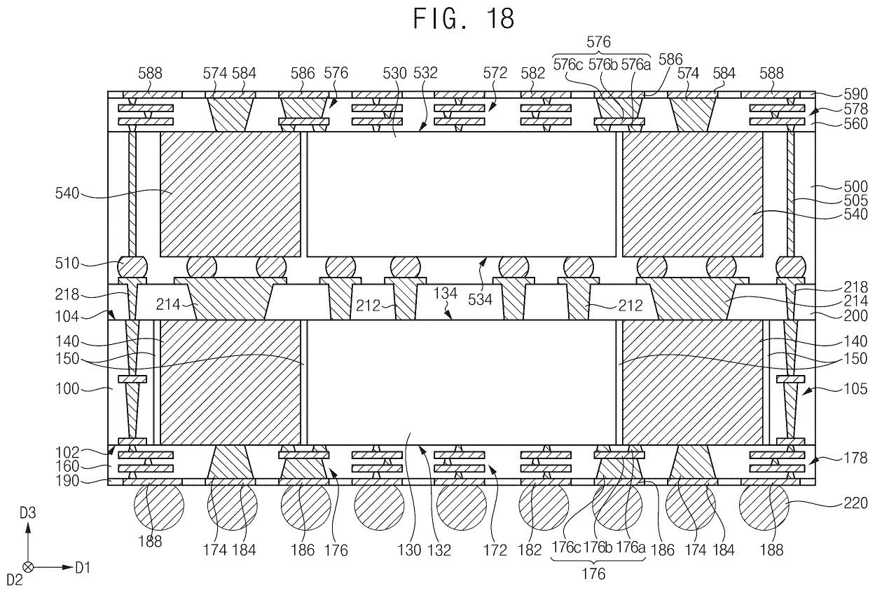

FIGS. 17 and 18 are cross-sectional views illustrating a package on package (POP), according to some example embodiments. Each of the POPs may include the semiconductor package of FIGS. 1 and 2 as a lower package and an upper package may be arranged on the lower package. A detailed description of the lower package including the semiconductor package of FIGS. 1 and 2 is omitted herein for the sake of brevity.

Referring to FIG. 17, the POP may include an upper package 400 stacked on the lower package via a second conductive connection member 410 and a first underfill member 420.

In some example embodiments, the upper package 400 may include a second substrate, a second semiconductor chip bonded to an upper surface of the second substrate, and a second molding member on the second substrate and covering the second semiconductor chip, and for example, substrate pads may be disposed beneath a lower surface of the second substrate.

In some example embodiments, the second semiconductor chip may include a memory device or a logic device.

In some example embodiments, a plurality of second conductive connection members 410 may be spaced apart from each other in the horizontal direction to contact the substrate pads, respectively, and may contact the fifth to seventh redistribution wiring structures 212, 214 and 218.

Thus, heat generated from the first semiconductor chip 130 included in the lower package may be transferred to the second substrate included in the upper package through the fifth and sixth redistribution wiring structures 212 and 214 and the second conductive connection member 410, and may be dissipated from the second substrate.

The first underfill member 420 may be disposed between the lower package and the upper package 400, and may cover the second conductive connection member 410 and the fifth to seventh redistribution wiring structures 212, 214 and 218. In some example embodiments, the first underfill member 420 may include an adhesive containing epoxy.

Referring to FIG. 18, the POP may include a third semiconductor chip 530, a second heat dissipation block 540, a third molding member 500, a conductive post 505 and a third RDL 560 that are positioned on the lower package.

The POP may further include a third conductive connection member 510, fifth to eighth conductive pads 582, 584, 586 and 588, and a third protective layer 590.

The third semiconductor chip 530 may include first and second surfaces 532 and 534 opposite to each other in the third direction D3, and the first surface 532 may be referred to as an active surface. The third semiconductor chip 530 may include a memory device or a logic device, and thus may also be referred to as a memory chip, a memory die, a logic chip or a logic die. In some example embodiments, the third semiconductor chip 530 may be aligned with the first semiconductor chip 130 in the third direction D3, however, example embodiments are not limited thereto, and, in some example embodiments, the third semiconductor chip 530 may be offset from the first semiconductor chip 130 in the third direction D3.

The second heat dissipation block 540 may be spaced apart from the third semiconductor chip 530 in the horizontal direction. In some example embodiments, the second heat dissipation block 540 may be aligned with the first heat dissipation block 140 in the third direction D3, however, example embodiments are not limited thereto, and, in some example embodiments, the second heat dissipation block 540 may be offset from the first heat dissipation block 140 in the third direction D3. The second heat dissipation block 540 may include first and second surfaces opposite to each other in the third direction D3.

The conductive post 505 may be spaced apart from the second heat dissipation block 540 in the horizontal direction. In some example embodiments, a plurality of conductive posts 505 may be spaced apart from each other in the horizontal direction. The conductive post 505 may include first and second surfaces opposite to each other in the third direction D3. In some example embodiments, the conductive post 505 may include copper.

The third conductive connection member 510 may contact and bond the upper surfaces of the fifth to seventh redistribution wiring structures 212, 214 and 218 included in the lower package, and the second surface 534 of the third semiconductor chip 530, the second surface of the second heat dissipation block 540 and the second surface of the conductive post 505 to each other. In some example embodiments, the third conductive connection member 510 may include solder and may be a conductive bump or a conductive ball.

The third molding member 500 may be disposed on the lower package and may cover sidewalls of the third semiconductor chip 530, the second heat dissipation block 540 and the conductive post 505. The third molding member 500 may further cover the third conductive connection member 510, and upper portions of the fifth to seventh redistribution wiring structures 212, 214 and 218 included in the lower package. In some example embodiments, the third molding member 500 may include EMC, ABF, and the like.

The third RDL 560 may be disposed on the first surface 532 of the third semiconductor chip 530, the first surface of the second heat dissipation block 540, the first surface of the conductive post 505 and the upper surface of the third molding member 500, and may include an eighth redistribution wiring structure 572, a ninth redistribution wiring structure, and tenth to eleventh redistribution wiring structures 576 and 578.

The eighth redistribution wiring structure 572 may be disposed on and contact the first surface 532 of the third semiconductor chip 530, the ninth redistribution wiring structure may be disposed on and contact the first surface of the second heat dissipation block 540, the tenth redistribution wiring structure 576 may be disposed on and contact the first surface 532 of the third semiconductor chip 530 and the first surface of the second heat dissipation block 540, and the eleventh redistribution wiring structure 578 may be disposed on the upper surface of the third molding member 500 and contact the conductive post 505.

The ninth redistribution wiring structure may include a seventh via 574, and the tenth redistribution wiring structure 576 may include an eighth via 576a, a second wiring 576b and a ninth via 576c.

Some of the eighth redistribution wiring structure 572, the ninth redistribution wiring structure and the tenth and eleventh redistribution wiring structures 576 and 578 may be electrically connected to each other. For example, the eighth and eleventh redistribution wiring structures 572 and 578 may be electrically connected to each other, and thus, electrical signals generated from the third semiconductor chip 530 may be transmitted to the eighth redistribution wiring structure 572 and the eleventh redistribution wiring structure 578. The electrical signals may be external to the third semiconductor chip 530 through the conductive post 505, the third conductive connection member 510, the wiring structure 105, the fourth redistribution wiring structure 178, the fourth conductive pads 188 and the first conductive connection member 220.

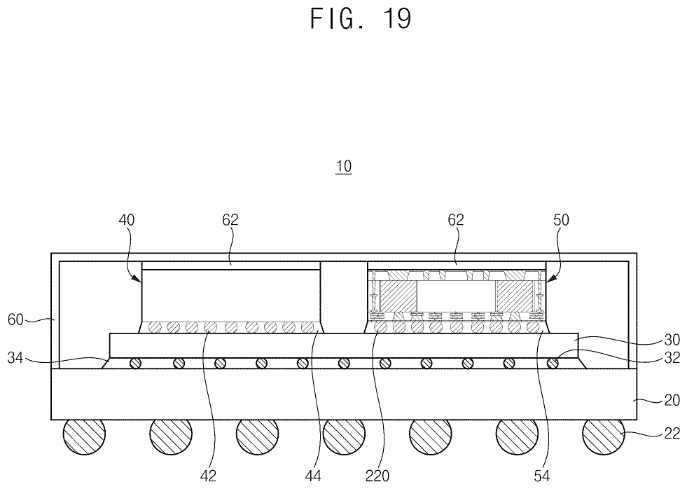

FIG. 19 is a cross-sectional view illustrating an electronic device, according to some example embodiments.

This electronic device may include the semiconductor package shown in FIGS. 1 and 2 as a second semiconductor device 50, however, example embodiments are not limited thereto, and the second semiconductor device 50 may also include the semiconductor package shown in each of FIGS. 12 to 18.

Referring to FIG. 19, an electronic device 10 may include a package substrate 20, an interposer 30, a first semiconductor device 40 and the second semiconductor device 50. The electronic device 10 may further include second, third and fourth underfill members 34, 44 and 54, a heat slug 60 and a heat dissipation member 62.

In some example embodiments, the electronic device 10 may be a memory module having a 2.5D package structure, and thus may include the interposer 30 for electrically connecting the first and second semiconductor devices 40 and 50 to each other.

In some example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, and the like. The memory device may be or include the semiconductor package of FIGS. 1 and 2.

In some example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a fifth conductive connection member 32. In some example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the fifth conductive connection member 32. The fifth conductive connection member 32 may include a micro-bump, for example. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a thermal compression bonding (TCB) method. In some example embodiments, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a sixth conductive connection member 42. For example, the sixth conductive connection member 42 may include a micro-bump.

Alternatively, the first semiconductor device 40 may be mounted on the interposer 30 by a wire bonding method, and the active surface of the first semiconductor device 40 may face upwardly.

The second semiconductor device 50 may be disposed on the interposer 30 and may be spaced apart from the first semiconductor device 40 in the horizontal direction. The second semiconductor device 50 may be mounted on and bonded with the interposer 30 by a thermal compression bonding (TCB) method. The conductive pads of the second semiconductor device 50 may be electrically connected to conductive pads of the interposer 30 by the first conductive connection member 220.

Although a single first semiconductor device 40 and a single second semiconductor device 50 are disposed on the interposer 30, however, example embodiments are not limited thereto, and a plurality of first semiconductor devices 40 and/or a plurality of second conductive devices 50 may be disposed on the interposer 30.

In some example embodiments, the second underfill member 34 may fill a space between the interposer 30 and the package substrate 20, and the third and fourth underfill members 44 and 54 may fill a space between the first semiconductor device 40 and the interposer 30 and a space between the second semiconductor device 50 and the interposer 30, respectively.

The second to fourth underfill members 34, 44 and 54 may include a material having a relatively higher fluidity that may effectively fill the relatively smaller space between the first and second semiconductor devices 40 and 50 and the interposer 30 and the relatively smaller space between the interposer 30 and the package substrate 20. For example, each of the second to fourth underfill members 34, 44 and 54 may include an adhesive containing an epoxy material.

In some example embodiments, the heat slug 60 may cover the package substrate 20 to thermally contact the first and second semiconductor devices 40 and 50. The heat dissipation member 62 may be disposed on an upper surface of each of the first and second semiconductor devices 40 and 50, and may include thermal interface material (TIM), for example. The heat slug 60 may thermally contact the first and second semiconductor devices 40 and 50 via the heat dissipation member 62.

A conductive pad may be formed at a lower portion of the package substrate 20, and a fourth conductive connection member 22 may be disposed beneath the conductive pad. In some example embodiments, a plurality of fourth conductive connection members 22 may be spaced apart from each other in the horizontal direction. The fourth conductive connection member 22 may be a solder ball, for example. The electronic device 10 may be mounted on a module board via the fourth conductive connection members 22 to form a memory module.

While several example embodiments have been provided in the present disclosure, it should be understood that the disclosed systems and methods might be embodied in many other specific forms without departing from the spirit or scope of the present disclosure. The present example embodiments are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various example embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor package comprising:
a first redistribution layer (RDL) including a first redistribution wiring structure;
a substrate on the first RDL and including a wiring structure, the substrate having a rectangular ring shape;
a semiconductor chip on the first RDL and in a space defined by the substrate;
a heat dissipation block between the semiconductor chip and the substrate on the first RDL, a planar area of the heat dissipation block being greater than a planar of the semiconductor chip;
a molding member on the first RDL and covering sidewalls of the semiconductor chip and the heat dissipation block and an inner sidewall of the substrate; and
a second RDL on the semiconductor chip, the heat dissipation block, the substrate and the molding member, and the second RDL including a second redistribution wiring structure.

2. The semiconductor package according to claim 1, wherein
the semiconductor chip has a rectangular shape including a pair of sides extending in a first direction and a pair of sides extending in a second direction, the second direction transverse the first direction, and
the semiconductor package further includes a plurality of heat dissipation blocks spaced apart from each other, the heat dissipation block being one of the plurality of heat dissipation blocks, and
each of the plurality of heat dissipation blocks is rectangularly shaped and includes a pair of sides extending in the first direction and a pair of sides extending in the second direction.

3. The semiconductor package according to claim 2, wherein the plurality of heat dissipation blocks includes:
first heat dissipation blocks on opposite sides of the semiconductor chip in the first direction; and
second heat dissipation blocks on opposite sides of the semiconductor chip in the second direction, and
wherein a length in the second direction of each of the first heat dissipation blocks is greater than a length in the second direction of the semiconductor chip.

4. The semiconductor package according to claim 3, wherein a length in the first direction of each of the second heat dissipation blocks is equal to a length in the first direction of the semiconductor chip.

5. The semiconductor package according to claim 2, wherein each heat dissipation block of the plurality of heat dissipation blocks is square shaped in a plan view.

6. The semiconductor package according to claim 5, wherein the semiconductor chip and the plurality of heat dissipation blocks are arranged in a lattice pattern in a plan view.

7. The semiconductor package according to claim 2, wherein the plurality of heat dissipation blocks are arranged in a clockwise direction or a counter-clockwise direction around the semiconductor chip.

8. The semiconductor package according to claim 1, wherein
the heat dissipation block includes two heat dissipation blocks, each of the two heat dissipation blocks having an “L” shape in a plan view, and
the two heat dissipation blocks are arranged in point symmetry around the semiconductor chip.

9. The semiconductor package according to claim 1, wherein the heat dissipation block has a rectangular ring shape surrounding the semiconductor chip in a plan view.

10. The semiconductor package according to claim 1, wherein the heat dissipation block includes copper, aluminum, gold, diamond or graphene.

11. The semiconductor package according to claim 1, wherein upper and lower surfaces of the heat dissipation block are coplanar with upper and lower surfaces, respectively, of the semiconductor chip.

12. The semiconductor package according to claim 1, wherein the heat dissipation block is electrically connected to the semiconductor chip through the first redistribution wiring structure.

13. The semiconductor package according to claim 1, wherein the second redistribution wiring structure includes:
a first via contacting an upper surface of the semiconductor chip; and
a second via contacting an upper surface of the heat dissipation block.

14. A semiconductor package comprising:
a first redistribution layer (RDL) including a first redistribution wiring structure;
a substrate on the first RDL and including a wiring structure, the substrate having a rectangular ring shape;
a semiconductor chip on the first RDL and in a space defined by the substrate;
heat dissipation blocks between the semiconductor chip and the substrate on the first RDL;
a molding member on the first RDL and covering sidewalls of the semiconductor chip and the heat dissipation blocks and an inner sidewall of the substrate; and
a second RDL on the semiconductor chip, the heat dissipation blocks, the substrate and the molding member, and the second RDL including a second redistribution wiring structure,
wherein at least a portion of the heat dissipation blocks is between the semiconductor chip and the substrate in a horizontal direction.

15. The semiconductor package according to claim 14, wherein upper and lower surfaces of each of the heat dissipation blocks are coplanar with upper and lower surfaces, respectively, of the semiconductor chip.

16. The semiconductor package according to claim 14, wherein each of the heat dissipation blocks is electrically connected to the semiconductor chip through the first redistribution wiring structure.

17. A semiconductor package comprising:
a first redistribution layer (RDL) including first to fourth redistribution wiring structures;
conductive connection members below and electrically connected to the first to fourth redistribution wiring structures, respectively;
a substrate on the first RDL and including a wiring structure, the substrate having a rectangular ring shape;
a semiconductor chip on the first RDL and in a space defined by the substrate;
a heat dissipation block between the semiconductor chip and the substrate on the first RDL, a planar area of the heat dissipation block being greater than a planar of the semiconductor chip;
a molding member on the first RDL and covering sidewalls of the semiconductor chip and the heat dissipation block and an inner sidewall of the substrate; and
a second RDL on the semiconductor chip, the heat dissipation block, the substrate and the molding member, and the second RDL including fifth to seventh redistribution wiring structures,
wherein the first redistribution wiring structure is on and contacts a lower surface of the semiconductor chip, the second redistribution wiring structure is on and contacts a lower surface of the heat dissipation block, the third redistribution wiring structure is on and contacts lower surfaces of the semiconductor chip and the heat dissipation block, and the fourth redistribution wiring structure is on and contacts a lower surface of the wiring structure, and
wherein the fifth redistribution wiring structure is on and contacts an upper surface of the semiconductor chip, the sixth redistribution wiring structure is on and contacts an upper surface of the heat dissipation block, and the seventh redistribution wiring structure is on and contacts an upper surface of the wiring structure.

18. The semiconductor package according to claim 17, wherein
the second redistribution wiring structure includes a first via, and
the third redistribution wiring structure includes,
a plurality of second vias contacting the semiconductor chip and the heat dissipation block;
a wiring contacting lower surfaces of the plurality of second vias; and
a third via contacting a lower surface of the wiring.

19. The semiconductor package according to claim 17, wherein the fifth redistribution wiring structure includes first vias extending through the second redistribution wiring structure and spaced apart from each other, and the sixth redistribution wiring structure includes a second via extending through the second redistribution wiring structure.

20. The semiconductor package according to claim 19, wherein a planar area of the second via is smaller than a planar area of the first via.
